(19) United States
(12) Patent Application Publication
(10) Pub. No.: US 2024/0421081 A1
(43) Pub. Date: Dec. 19, 2024

(54) MEMORY DEVICE

(71) Applicant: SAMSUNG ELECTRONICS CO., LTD., Suwon-si (KR)

(72) Inventor: Seulji Song, Suwon-si (KR)

(21) Appl. No.: 18/631,666

(22) Filed: Apr. 10, 2024

(30) Foreign Application Priority Data
Jun. 19, 2023 (KR) 10-2023-0078206

(51) Int. Cl. H01L 23/528; H10B 63/00; H10N 70/00

(52) U.S. Cl. CPC H01L 23/5283; H10B 63/84; H10N 70/8822; H10N 70/8825; H10N 70/8828

(57) ABSTRACT

A memory device includes a first conductive line extending in a first horizontal direction, a second conductive line extending in a second horizontal direction, and a memory cell extending in a vertical direction between the first conductive line and the second conductive line. The memory cell includes a lower electrode layer, a switching pattern, and an upper electrode layer, which are sequentially stacked on the first conductive line. The switching pattern includes a chalcogenide layer including a chalcogen element of group VI of the periodic table, and an element of group IV and an element of group V of the periodic table, which are chemically bonded to the group VI chalcogen element. The switching pattern is configured to have a three-level concentration gradient of the group IV element or the group V element in the vertical direction.

### CROSS-REFERENCE TO RELATED APPLICATION

This application claims priority under 35 U.S.C. § 119 to Korean Patent Application No. 10-2023-0078206, filed on Jun. 19, 2023, in the Korean Intellectual Property Office, the disclosure of which is incorporated by reference herein in its entirety.

### BACKGROUND

Along with the trend toward light, thin, and small electronic products, the demand for high integration of memory devices has increased. A memory device of a 3D cross point array structure in which a memory cell is arranged at the point of intersection between two conductive lines intersecting each other has been proposed. A memory device of a 3D cross point array structure requires good high-speed operation and high operation reliability.

### SUMMARY

The disclosure relates to a memory device capable of having a good high-speed operation and high operation reliability.

According to an aspect of the present disclosure, there is provided a memory device including a first conductive line extending in a first horizontal direction, a second conductive line extending in a second horizontal direction, and a memory cell extending in a vertical direction between the first conductive line and the second conductive line.

The memory cell includes a lower electrode layer, a switching pattern, and an upper electrode layer, which are sequentially stacked on the first conductive line. The switching pattern includes a chalcogenide layer including a chalcogen element of group VI of the periodic table, and an element of group IV and an element of group V of the periodic table, which are chemically bonded to the group VI chalcogen element. The switching pattern is configured to have a three-level concentration gradient of the group IV element or the group V element in the vertical direction.

According to another aspect of the present disclosure, there is provided a memory device including a first conductive line extending in a first horizontal direction, a second conductive line extending in a second horizontal direction, and a memory cell extending in a vertical direction between the first conductive line and the second conductive line. The memory cell includes a lower electrode layer, a switching pattern, and an upper electrode layer, which are sequentially stacked on the first conductive line.

The switching pattern includes a chalcogenide layer including a chalcogen element of group VI of the periodic table and a combination of an element of group IV and an element of group V of the periodic table, which is chemically bonded to the group VI chalcogen element.

The switching pattern includes a first interface region on the lower electrode layer, a core region on the first interface region, and a second interface region on the core region. A concentration of the group IV element in each of the first interface region and the second interface region is lower than a concentration of the group IV element in the core region. A concentration of the group V element in each of the first interface region and the second interface region is higher than a concentration of the group V element in the core region.

According to another aspect of the present disclosure, there is provided a memory device including a first conductive line extending in a first horizontal direction, a second conductive line extending in a second horizontal direction, and a memory cell extending in a vertical direction between the first conductive line and the second conductive line.

The memory cell includes a lower electrode layer, a switching pattern, and an upper electrode layer, which are sequentially stacked on the first conductive line. The switching pattern includes a chalcogenide layer including a chalcogen element of group VI of the periodic table and a combination of an element of group IV and an element of group V of the periodic table, which is chemically bonded to the group VI chalcogen element.

The switching pattern includes a first interface region on the lower electrode layer, a core region on the first interface region, and a second interface region on the core region. The core region includes an impurity layer of a first conductive type, and the first interface region and the second interface region include an impurity layer of a second conductive type that is opposite to the first conductive type.

### BRIEF DESCRIPTION OF THE DRAWINGS

Implementations of this disclosure will be more clearly understood from the following detailed description taken in conjunction with the accompanying drawings in which:

FIG. 1 is a top view of a memory device according to some implementations;

FIG. 2 is a cross-sectional view taken along line II-II′ of the memory device of FIG. 1;

FIG. 3 illustrates, in a depth direction, the concentrations of elements constituting a switching pattern of FIG. 2;

FIG. 4 illustrates the semiconductor characteristics of a switching pattern in memory cells of FIGS. 1 and 2;

FIG. 5 illustrates the current and voltage characteristics of memory cells of FIGS. 1 and 2;

FIG. 6 illustrates the write characteristics of a memory cell when a positive voltage is applied to a second interface region constituting the switching pattern of FIG. 4;

FIGS. 7A and 7B illustrate the read characteristics of a memory cell when a positive voltage is applied to the second interface region constituting the switching pattern of FIG. 6, and FIGS. 8A and 8B illustrate the read characteristics of a memory cell when a negative voltage is applied to the second interface region constituting the switching pattern of FIG. 6;

FIG. 9 illustrates the write characteristics of a memory cell when a negative voltage is applied to the second interface region constituting the switching pattern of FIG. 4;

FIGS. 10A and 10B illustrate the read characteristics of a memory cell when a positive voltage is applied to the second interface region constituting the switching pattern of FIG. 9, and FIGS. 11A and 11B illustrate the read characteristics of a memory cell when a negative voltage is applied to the second interface region constituting the switching pattern of FIG. 9;

FIGS. 12 to 17 are cross-sectional views for describing a method of manufacturing the memory device of FIGS. 1 and 2, according to some implementations;

FIGS. 18 to 21 are cross-sectional views for describing a method of manufacturing the memory device of FIGS. 1 and 2, according to some implementations;

FIG. 22 is a block diagram of a memory device according to some implementations;

FIG. 23 is a block diagram of a data processing system including a memory device according to some implementations; and

FIG. 24 is a block diagram of a data processing system including a memory device according to some implementations.

### DETAILED DESCRIPTION

Hereinafter, implementations will be described in detail with reference to the accompanying drawings. While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described below as acting in certain combinations and even initially be claimed as such, one or more features from a combination can in some cases be excised from the combination, and the combination may be directed to a subcombination or variation of a subcombination.

In the specification, an expression in the singular includes an expression in the plural unless they are clearly different from each other in context. In the specification, the drawings are exaggerated to more clearly describe the implementations.

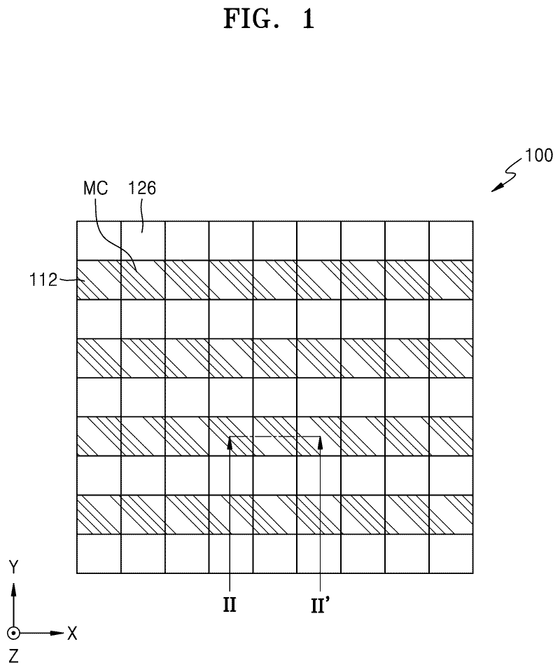

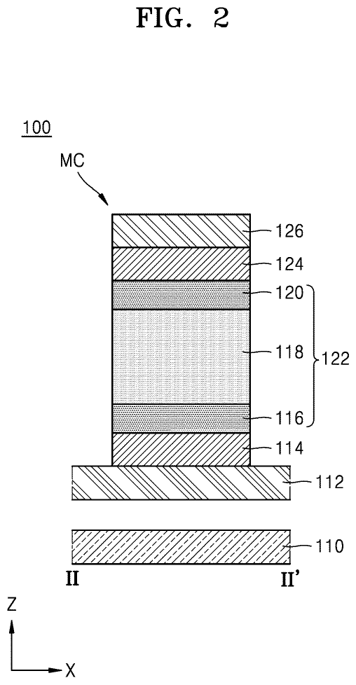

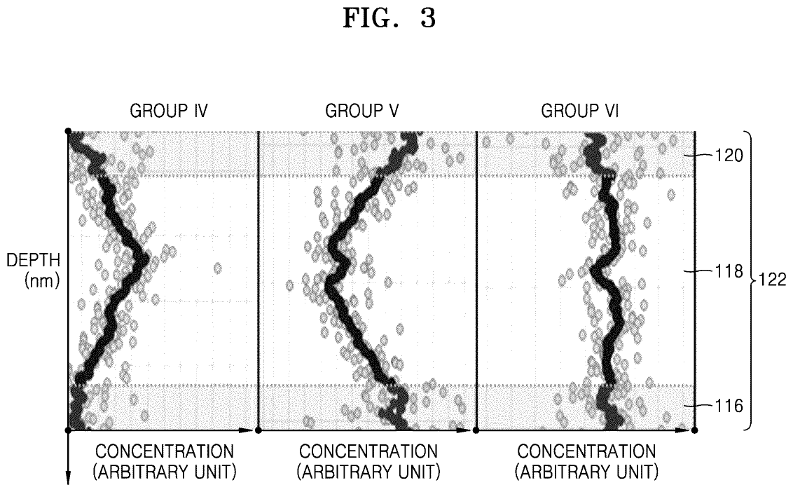

FIG. 1 is a top view of a memory device 100 according to some implementations, FIG. 2 is a cross-sectional view taken along line II-II′ of the memory device 100 of FIG. 1, and FIG. 3 illustrates, in a depth direction, the concentrations of elements constituting a switching pattern 122 of FIG. 2.

Particularly, as shown in FIG. 1, the memory device 100 includes a plurality of first conductive lines 112, a plurality of second conductive lines 126 on the plurality of first conductive lines 112, and a plurality of memory cells MC respectively positioned at the points where the plurality of first conductive lines 112 intersect with the plurality of second conductive lines 126. The plurality of memory cells MC may have an array structure in which the plurality of memory cells MC are separated from each other in a first horizontal direction (the X direction) and a second horizontal direction (the Y direction). The memory device 100 includes a memory cell MC above a substrate 110 as shown in FIG. 2.

The substrate 110 may include a semiconductor material, such as a group IV semiconductor material, a group III-V semiconductor material, or a group II-VI semiconductor material. The group IV semiconductor material may include, for example, silicon (Si), germanium (Ge), or SiGe. The group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The group II-VI semiconductor material may include, for example, zinc telluride (ZnTe) or cadmium sulfide (CdS).

The plurality of first conductive lines 112 may extend to be parallel to each other in the first horizontal direction (the X direction) and be separated from each other in the second horizontal direction (the Y direction) as shown in FIG. 1. The plurality of second conductive lines 126 may extend to be parallel to each other in the second horizontal direction (the Y direction) and be separated from each other in the first horizontal direction (the X direction).

In some implementations, a first conductive line 112 may be referred to as a word line, and a second conductive line 126 may be referred to as a bit line. Each of the first conductive line 112 and the second conductive line 126 may include a metal, conductive metal nitride, conductive metal oxide, or a combination thereof.

For example, each of the first conductive line 112 and the second conductive line 126 may include tungsten (W), tungsten nitride (WN), gold (Au), silver (Ag), copper (Cu), aluminum (Al), titanium aluminum nitride (TiAlN), iridium (Jr), platinum (Pt), palladium (Pd), ruthenium (Ru), zirconium (Zr), rhodium (Rh), nickel (Ni), cobalt (Co), chromium (Cr), tin (Sn), zinc (Zn), indium tin oxide (ITO), or a combination thereof.

The memory cell MC may extend in the vertical direction (the Z direction) between the first conductive line 112 and the second conductive line 126 as shown in FIG. 2. The memory cell MC includes a lower electrode layer 114, the switching pattern 122, and an upper electrode layer 124 stacked on the first conductive line 112.

The lower electrode layer 114 may be provided to prevent diffusion and block thermal transfer. The lower electrode layer 114 may include a metal, conductive metal nitride, conductive metal oxide, or a carbon-based material. For example, the lower electrode layer 114 may include a carbon electrode or a carbon nitride electrode. The switching pattern 122 may be configured to have a bidirectional switching characteristic, i.e., a bidirectional rectification characteristic. The bidirectional switching characteristic of the switching pattern 122 will be described below in more detail.

The switching pattern 122 may have a resistance varying according to the magnitude of a voltage applied to both ends of the switching pattern 122. The switching pattern 122 may include a material having an ovonic threshold switching (OTS) characteristic. Inn some implementations, when a voltage lower than a threshold voltage is applied to the switching pattern 122, the switching pattern 122 may be in a high resistance state in which little current flows through the switching pattern 122. When a voltage higher than the threshold voltage is applied to the switching pattern 122, the switching pattern 122 may be in a low resistance state in which a current flows through the switching pattern 122. Accordingly, the switching pattern 122 may be a memory storage element.

The switching pattern 122 may include a single film. In some implementations, the switching pattern 122 may include a chalcogenide layer including a chalcogen element of group VI of the periodic table and an element of group IV and an element of group V of the periodic table, which are chemically bonded to the group VI chalcogen element. The group VI chalcogen element may include at least one of tellurium (Te), selenium (Se), and sulfur (S). The bonded group V element may include at least one of arsenic (As), antimony (Sb), and phosphorous (P). The bonded group IV element may include at least one of Si and Ge.

In some implementations, the switching pattern 122 may further include a doping element of group III of the periodic table in addition to the elements described above. The group III doping element may include at least one of indium (In), gallium (Ga), and aluminum (Al).

The switching pattern 122 may be configured to have a three-level concentration gradient of the group IV element or the group V element in the vertical direction (the Z direction). The switching pattern 122 may be configured to have a three-level composition gradient of the group IV element or the group V element in the vertical direction (the Z direction).

In some implementations, the switching pattern 122 may have a low concentration level, a high concentration level, and a low concentration level of the group IV element in the vertical direction (the Z direction). The switching pattern 122 may have a high concentration level, a low concentration level, and a high concentration level of the group V element in the vertical direction (the Z direction).

In some implementations, the switching pattern 122 includes a first interface region 116 formed on the lower electrode layer 114, a core region 118 formed on the first interface region 116, and a second interface region 120 formed on the core region 118 as shown in FIG. 2. FIG. 3 shows, in a depth direction, the concentrations of elements constituting the switching pattern 122 of FIG. 2. The depth direction may be a reverse vertical direction (the-Z direction) of FIG. 2.

In some implementations, as shown in FIG. 3, the concentration of the group IV element in each of the first interface region 116 and the second interface region 120 may be lower than the concentration of the group IV element in the core region 118. The concentration of the group V element in each of the first interface region 116 and the second interface region 120 may be higher than the concentration of the group V element in the core region 118. The concentration of the group VI chalcogen element in each of the first interface region 116 and the second interface region 120 may be the same as the concentration of the group VI chalcogen element in the core region 118.

In some implementations, the first interface region 116 and the second interface region 120 constituting the switching pattern 122 may include about 10 atom % to about 20 atom % of a group IV element, about 25 atom % to about 40 atom % of a group V element, and about 40 atom % to about 65 atom % of a group VI element. The core region 118 constituting the switching pattern 122 may include about 15 atom % to about 25 atom % of a group IV element, about 20 atom % to about 30 atom % of a group V element, and about 45 atom % to about 65 atom % of a group VI element.

The upper electrode layer 124 may be provided to prevent diffusion and block thermal transfer. The upper electrode layer 124 may include a metal, conductive metal nitride, conductive metal oxide, or a carbon-based material. For example, the upper electrode layer 124 may include a carbon electrode or a carbon nitride electrode.

In the memory device 100 described above, the concentrations of elements constituting the switching pattern 122 may influence the threshold voltage of the memory cell MC, and the threshold voltage may be used to determine the logical state of the memory cell MC. Accordingly, the memory cell MC may be a self-selecting memory cell or a selector only memory cell capable of programming and detecting a logical state based on the concentrations of elements constituting one switching pattern 122.

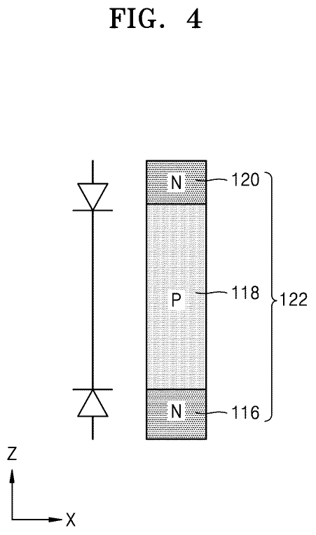

FIG. 4 illustrates the semiconductor characteristics of the switching pattern 122 in the memory cell MC of FIGS. 1 and 2, and FIG. 5 illustrates the current and voltage characteristics of the memory cell MC of FIGS. 1 and 2.

Particularly, as described above, the switching pattern 122 of the memory cell MC (see FIGS. 1 and 2) according to some implementations may be configured have a three-level concentration gradient of a group IV element or a group V element in the vertical direction (the Z direction).

In some implementations, the switching pattern 122 includes the first interface region 116, the core region 118, and the second interface region 120 as shown in FIG. 4. The core region 118 may include a first conductive type semiconductor layer, i.e., a P-type semiconductor layer, which can be an impurity layer.

The first interface region 116 and the second interface region 120 may include a second conductive type semiconductor layer, i.e., an N-type semiconductor layer, that is opposite to the first conductive type semiconductor layer. The N-type semiconductor layer can also be an impurity layer. The switching pattern 122 includes the first interface region 116, the core region 118, and the second interface region 120 and may be represented by two diodes connected in series as shown in FIG. 4.

In some implementations, the switching pattern 122 having a three-level concentration gradient may be formed, in a manufacturing process, by a film forming process, e.g., reactive sputtering or an in-situ type by controlling a process variable of atomic layer deposition (ALD). The in-situ type may indicate immediately forming a three-level switching pattern (or switching material layer) in a film forming process.

In some implementations, the switching pattern 122 having a three-level concentration gradient may be formed by an ex-situ type using the reactivity difference (or the etching amount difference) between etching gas and materials to be etched during a film patterning process in a manufacturing process. The ex-situ type may indicate forming the switching pattern 122 having a three-level concentration gradient in a manufacturing process of patterning a switching material layer after forming a film.

As described above, the memory cell MC (see FIGS. 1 and 2) according to some implementations includes the switching pattern 122 including the first interface region 116 of a second conductive type semiconductor layer (an N-type semiconductor layer), the core region 118 of a first conductive type semiconductor layer (a P-type semiconductor layer), and the second interface region 120 of the second conductive type semiconductor layer (the N-type semiconductor layer).

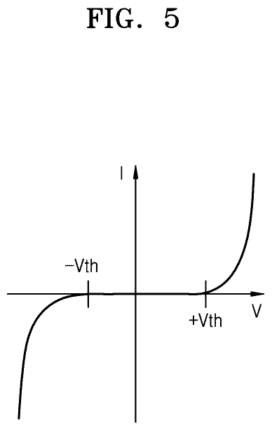

Accordingly, the memory cell MC (see FIGS. 1 and 2) according to some implementations exhibits a switching characteristic at a positive threshold voltage +Vth when a positive voltage is applied to the switching pattern 122 as shown in FIG. 5.

The memory cell MC (see FIGS. 1 and 2) according to some implementations exhibits a switching characteristic at a negative threshold voltage-Vth when a negative voltage is applied to the switching pattern 122 as shown in FIG. 5. For example, the positive voltage or the negative voltage may be applied to the second interface region 120 constituting the switching pattern 122.

As described above, the memory cell MC (see FIGS. 1 and 2) according to some implementations may exhibit a switching characteristic of enabling rectification in both directions including the vertical direction (the Z direction) from the first interface region 116 to the second interface region 120 and the reverse vertical direction (the-Z direction) from the second interface region 120 to the first interface region 116. In addition, the memory device 100 (see FIGS. 1 and 2) according to some implementations may require the positive voltage and the negative voltage for an operation.

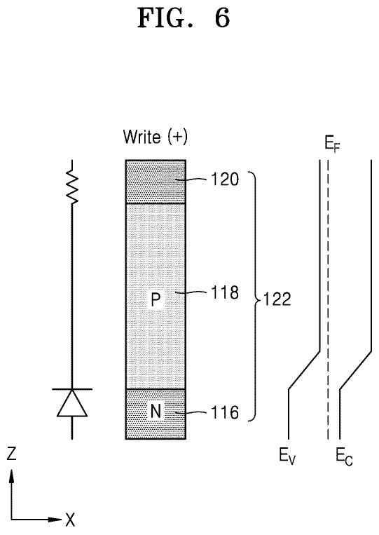

FIG. 6 illustrates the write characteristics of a memory cell when the positive voltage is applied to the second interface region 120 constituting the switching pattern 122 of FIG. 4.

Particularly, the positive voltage (i.e., an operating voltage) may be applied to the second interface region 120 constituting the switching pattern 122 to perform a write operation, e.g., a set operation, on the memory cell MC (see FIGS. 1 and 2). When a write operation is performed by applying the positive voltage to the second interface region 120 constituting the switching pattern 122, the concentration gradients of elements, e.g., a group V element or a group IV element, included in the first interface region 116 and the second interface region 120 constituting the switching pattern 122 may be equally maintained.

When a write operation is performed by applying the positive voltage to the second interface region 120 constituting the switching pattern 122, a microstructure of the switching pattern 122 may not change, and amorphous may be maintained.

When a write operation is performed by applying the positive voltage to the second interface region 120 constituting the switching pattern 122, holes are injected to the second interface region 120. The holes injected to the second interface region 120 may be trapped in the group V element constituting the second interface region 120. The injected holes may be recombined with electrons such that the second interface region 120 changes to a depletion region.

By doing this, as shown in FIG. 6, the second interface region 120 may indicate one resistor, and the core region 118 and the first interface region 116 may become one diode. The switching pattern 122 may have a form in which one resistor is connected in series to one diode.

FIG. 6 shows an energy band diagram among the first interface region 116, the core region 118, and the second interface region 120. In FIG. 6, E_{V} may denote a valence band energy level, E_{F} may denote a Fermi energy level, and E_{C} may denote a conduction band energy level. As shown in FIG. 6, the energy levels of the core region 118 and the second interface region 120 may be high, and the energy level of the first interface region 116 may be low.

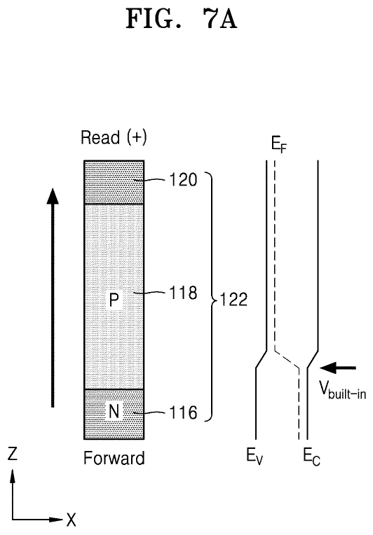

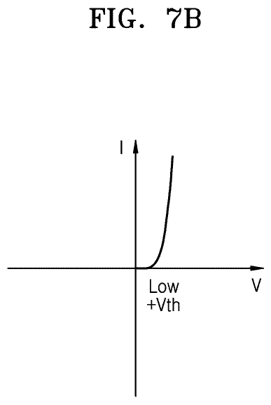

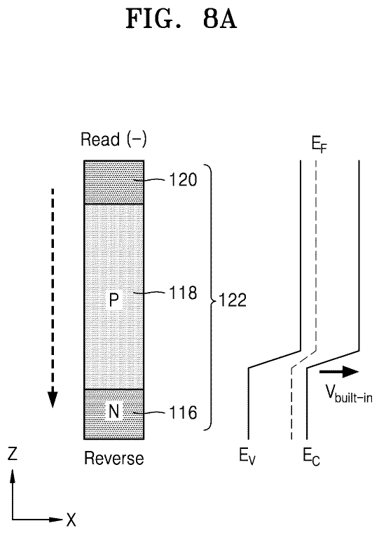

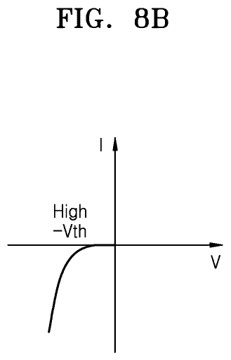

FIGS. 7A and 7B illustrate the read characteristics of a memory cell when the positive voltage is applied to the second interface region 120 constituting the switching pattern 122 of FIG. 6, and FIGS. 8A and 8B illustrate the read characteristics of the memory cell when the negative voltage is applied to the second interface region 120 constituting the switching pattern 122 of FIG. 6.

Particularly, FIGS. 7A, 7B, 8A, and 8B illustrate the read characteristics of the memory cell after performing a write operation by applying the positive voltage to the second interface region 120 constituting the switching pattern 122 as described above with reference to FIG. 6.

As shown in FIG. 7A, when the memory cell is read by applying the positive voltage to the second interface region 120 constituting the switching pattern 122, a forward bias may be applied to the core region 118 of the first conductive type semiconductor layer (the P-type semiconductor layer) and the second interface region 120 of the second conductive type semiconductor layer (the N-type semiconductor layer).

The switching pattern 122 may have a low built-in potential as shown in the energy band diagram of FIG. 7A. Accordingly, the memory cell may exhibit a switching characteristic at a positive threshold voltage Low +Vth as shown in the current and voltage characteristics of FIG. 7B.

As shown in FIG. 8A, when the memory cell is read by applying the negative voltage to the second interface region 120 constituting the switching pattern 122, a reverse bias may be applied to the core region 118 of the first conductive type semiconductor layer (the P-type semiconductor layer) and the second interface region 120 of the second conductive type semiconductor layer (the N-type semiconductor layer).

The switching pattern 122 may have a high built-in potential as shown in the energy band diagram of FIG. 8A. Accordingly, the memory cell may exhibit a switching characteristic at a negative threshold voltage High −Vth as shown in the current and voltage characteristics of FIG. 8B.

The read characteristics of the memory call according to some implementations described above with reference to FIGS. 7A to 8B may be determined by a built-in potential. Accordingly, the critical dimension (CD) dependency of the memory call according to some implementations may be reduced, thereby making a manufacturing process easy.

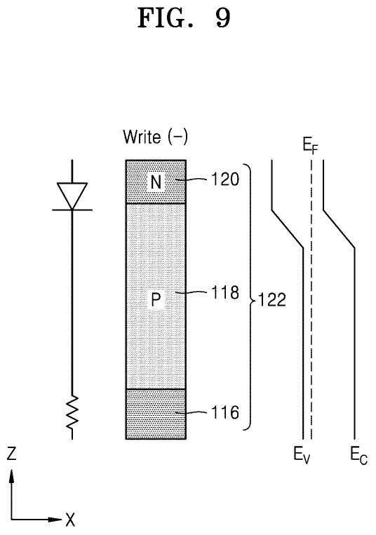

FIG. 9 illustrates the write characteristics of a memory cell when the negative voltage is applied to the second interface region 120 constituting the switching pattern 122 of FIG. 4.

Particularly, the negative voltage (i.e., the operating voltage) may be applied to the second interface region 120 constituting the switching pattern 122 to perform a write operation, e.g., a reset operation, on the memory cell MC (see FIGS. 1 and 2). When a write operation is performed by applying not the positive voltage but the negative voltage to the second interface region 120 constituting the switching pattern 122, the concentration gradients of elements, e.g., a group V element or a group IV element, included in the first interface region 116 and the second interface region 120 constituting the switching pattern 122 may be equally maintained.

When a write operation is performed by applying the negative voltage to the second interface region 120 constituting the switching pattern 122, a microstructure of the switching pattern 122 may not change, and amorphous may be maintained.

When a write operation is performed by applying the negative voltage to the second interface region 120 constituting the switching pattern 122, holes are injected to the first interface region 116. The holes injected to the first interface region 116 may be trapped in the group V element constituting the first interface region 116. The injected holes may be recombined with electrons such that the first interface region 116 changes to a depletion region.

By doing this, as shown in FIG. 9, the first interface region 116 may indicate one resistor, and the core region 118 and the second interface region 120 may become one diode. The switching pattern 122 may have a form in which one resistor is connected in series to one diode.

FIG. 9 shows an energy band diagram among the first interface region 116, the core region 118, and the second interface region 120. In FIG. 9, E_{V} may denote a valence band energy level, E_{F} may denote a Fermi energy level, and E_{C} may denote a conduction band energy level. As shown in FIG. 9, the energy levels of the core region 118 and the first interface region 116 may be high, and the energy level of the second interface region 120 may be low.

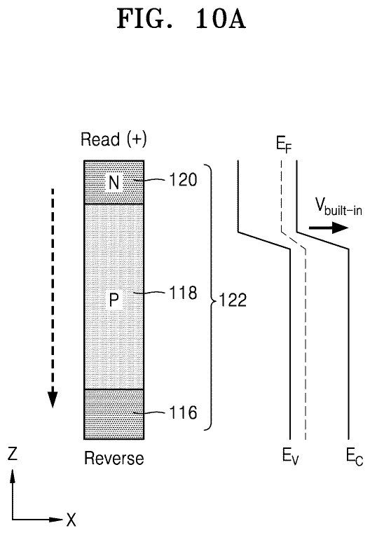

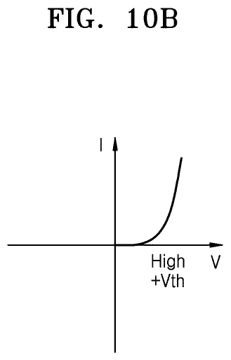

FIGS. 10A and 10B illustrate the read characteristics of a memory cell when the positive voltage is applied to the second interface region 120 constituting the switching pattern 122 of FIG. 9, and FIGS. 11A and 11B illustrate the read characteristics of the memory cell when the negative voltage is applied to the second interface region 120 constituting the switching pattern 122 of FIG. 9.

Particularly, FIGS. 10A, 10B, 11A, and 11B illustrate the read characteristics of the memory cell after performing a write operation by applying the negative voltage to the second interface region 120 constituting the switching pattern 122 as described above with reference to FIG. 9.

As shown in FIG. 10A, when the memory cell is read by applying the positive voltage to the second interface region 120 constituting the switching pattern 122, a reverse bias may be applied to the core region 118 of the first conductive type semiconductor layer (the P-type semiconductor layer) and the second interface region 120 of the second conductive type semiconductor layer (the N-type semiconductor layer).

The switching pattern 122 may have a high built-in potential as shown in the energy band diagram of FIG. 10A. Accordingly, the memory cell may exhibit a switching characteristic at a positive threshold voltage High +Vth as shown in the current and voltage characteristics of FIG. 10B.

As shown in FIG. 11A, when the memory cell is read by applying the negative voltage to the second interface region 120 constituting the switching pattern 122, a positive bias may be applied to the core region 118 of the first conductive type semiconductor layer (the P-type semiconductor layer) and the second interface region 120 of the second conductive type semiconductor layer (the N-type semiconductor layer).

The switching pattern 122 may have a low built-in potential as shown in the energy band diagram of FIG. 11A. Accordingly, the memory cell may exhibit a switching characteristic at a negative threshold voltage Low −Vth as shown in the current and voltage characteristics of FIG. 11B.

The read characteristics of the memory call according to some implementations described above with reference to FIGS. 10A to 11B may be determined by a built-in potential. Accordingly, the CD dependency of the memory call according to some implementations may be reduced, thereby making a manufacturing process easy.

The memory cell of a memory device according to some implementations described above with reference to FIGS. 6 to 11B operates by movement of carriers (holes or electrons) in the switching pattern 122 and may be thus good at a high-speed operation. In addition, the memory cell of the memory device according to some implementations described above with reference to FIGS. 6 to 11B has constant concentration gradients of elements constituting the switching pattern 122 during an operation and may thus have high operation reliability.

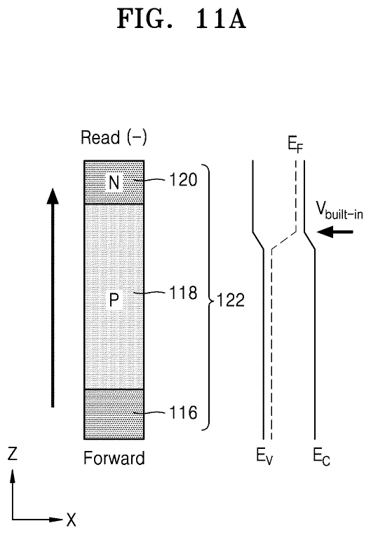

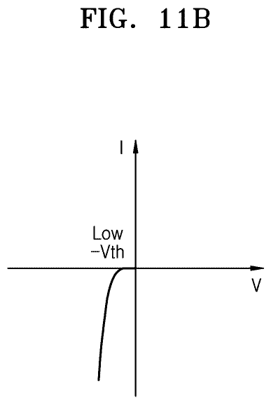

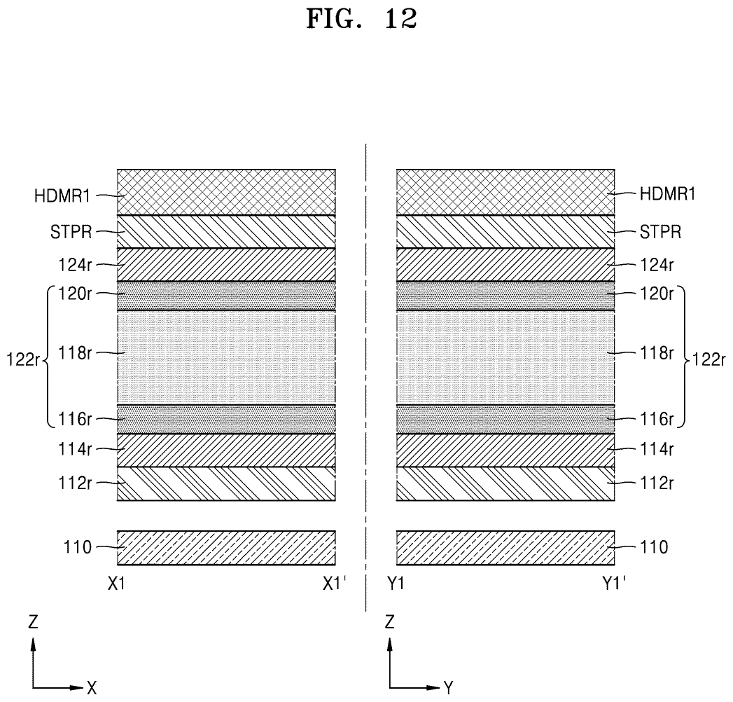

FIGS. 12 to 17 are cross-sectional views for describing a method of manufacturing the memory device 100 of FIGS. 1 and 2, according to some implementations.

Particularly, FIGS. 12 to 17 may include cross-sectional views taken along random line X1-X1′ in the first horizontal direction (the X direction) and cross-sectional views taken along random line Y1-Y1′ in the second horizontal direction (the Y direction) in FIG. 1. In FIGS. 12 to 17, like reference numerals in FIGS. 1 and 2 denote like members.

Referring to FIG. 12, a first conductive line material layer 112r, a lower electrode material layer 114r, a switching material layer 122r, an upper electrode material layer 124r, an etching prevention material layer STPR, and a first hard mask material layer HDMR1 are formed above the substrate 110.

The substrate 110 may include a semiconductor material, such as a group IV semiconductor material, a group III-V semiconductor material, or a group II-VI semiconductor material, as described above. An intermediate layer, such as an interlayer insulating material layer, may be formed on the substrate 110 but is omitted herein.

The first conductive line material layer 112r is formed above the substrate 110. The first conductive line material layer 112r may include a metal, conductive metal nitride, conductive metal oxide, or a combination thereof as described above.

The lower electrode material layer 114r is formed on the first conductive line material layer 112r. The lower electrode material layer 114r may include a metal, conductive metal nitride, conductive metal oxide, or a carbon-based material as described above. For example, the lower electrode material layer 114r may include carbon (C) or carbon nitride.

The switching material layer 122r is formed on the lower electrode material layer 114r. The switching material layer 122r may include a chalcogenide layer including a chalcogen element of group VI of the periodic table and an element of group IV and an element of group V of the periodic table, which are chemically bonded to the group VI chalcogen element, as described above. The group VI chalcogen element may include at least one of Te, Se, and S. The bonded group V element may include at least one of As, Sb, and P. The bonded group IV element may include at least one of Si and Ge.

In some implementations, the switching material layer 122r may further include a doping element of group III of the periodic table in addition to the elements described above. The group III doping element may include at least one of In, Ga, and Al.

In addition, the switching material layer 122r may be formed to have a three-level concentration gradient of the group IV element or the group V element in the vertical direction (the Z direction). For example, the switching material layer 122r may have a low concentration level, a high concentration level, and a low concentration level of the group IV element in the vertical direction (the Z direction). The switching material layer 122r may have a high concentration level, a low concentration level, and a high concentration level of the group V element in the vertical direction (the Z direction).

In some implementations, the switching material layer 122r includes a first interface material layer 116r, a core material layer 118r formed on the first interface material layer 116r, and a second interface material layer 120r formed on the core material layer 118r.

In some implementations, the concentration of the group IV element in each of the first interface material layer 116r and the second interface material layer 120r may be lower than the concentration of the group IV element in the core material layer 118r. The concentration of the group V element in each of the first interface material layer 116r and the second interface material layer 120r may be higher than the concentration of the group V element in the core material layer 118r. The concentration of the group VI chalcogen element in each of the first interface material layer 116r and the second interface material layer 120r may be the same as the concentration of the group VI chalcogen element in the core material layer 118r.

In some implementations, the first interface material layer 116r and the second interface material layer 120r may include about 10 atom % to about 20 atom % of a group IV element, about 25 atom % to about 40 atom % of a group V element, and about 40 atom % to about 65 atom % of a group VI element. The core material layer 118r may include about 15 atom % to about 25 atom % of a group IV element, about 20 atom % to about 30 atom % of a group V element, and about 45 atom % to about 65 atom % of a group VI element.

In some implementations, the switching material layer 122r having a three-level concentration gradient may be formed, in a manufacturing process, by a film forming process, e.g., reactive sputtering or an in-situ type by controlling a process variable of ALD. The in-situ type indicates immediately forming a three-level concentration gradient in an operation of forming the switching material layer 122r.

The upper electrode material layer 124r is formed on the switching material layer 122r. The upper electrode material layer 124r may include a metal, conductive metal nitride, conductive metal oxide, or a carbon-based material as described above. For example, the upper electrode material layer 124r may include C or carbon nitride.

The etching prevention material layer STPR is formed on the upper electrode material layer 124r. The etching prevention material layer STPR may include silicon nitride. The first hard mask material layer HDMR1 is formed on the etching prevention material layer STPR. The first hard mask material layer HDMR1 may include a silicon oxide layer, a silicon nitride layer, a polysilicon layer, or another dielectric layer.

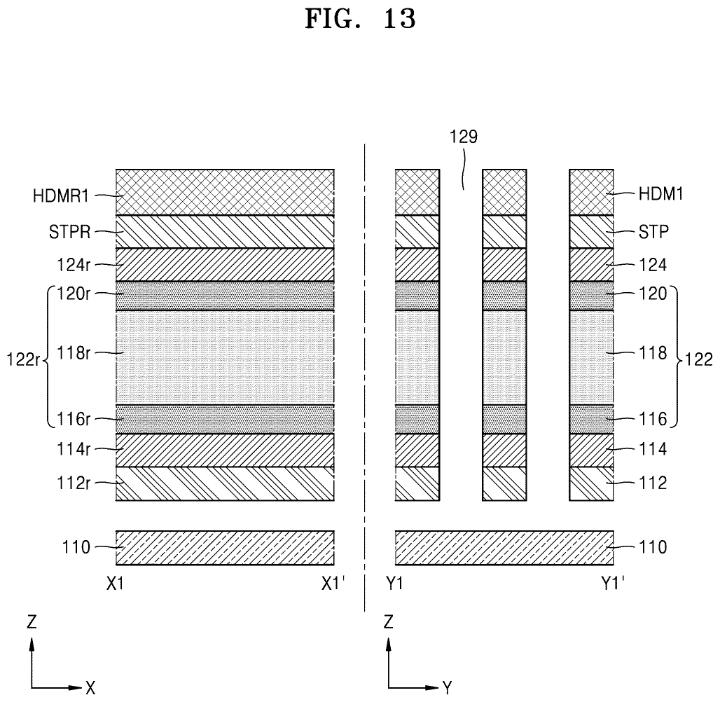

Referring to FIG. 13, a first hard mask pattern HDM1 is formed by patterning the first hard mask material layer HDMR1 (see FIG. 12). The first hard mask pattern HDM1 may be patterned using a photoresist pattern formed on the first hard mask material layer HDMR1 (see FIG. 12) through a photolithography process. In some implementations, the first hard mask pattern HDM1 may have a very fine pitch less than or equal to tens of nm.

The first hard mask pattern HDM1 may extend in the first horizontal direction (the X direction). Multiple instances of first hard mask patterns HDM1 may be separated from each other in the second horizontal direction (the Y direction). The instances of the first hard mask patterns HDM1 extend on the X1-X1′ cross-section of FIG. 13 and are separated from each other on the Y1-Y1′ cross-section of FIG. 13.

The first hard mask pattern HDM1 is used as an etching mask to etch the etching prevention material layer STPR (see FIG. 12), the upper electrode material layer 124r (see FIG. 12), the switching material layer 122r (see FIG. 12), the lower electrode material layer 114r (see FIG. 12), and the first conductive line material layer 112r (see FIG. 12).

Accordingly, as shown on the Y1-Y1′ cross-section of FIG. 13, the first conductive line 112, the lower electrode layer 114, the switching pattern 122, the upper electrode layer 124, and an etching prevention layer STP may be formed above the substrate 110. The plurality of first conductive lines 112 may extend to be parallel to each other in the first horizontal direction (the X direction) and be separated from each other in the second horizontal direction (the Y direction) as described above. The first conductive line 112 may be referred to as a word line.

As shown on the Y1-Y1′ cross-section of FIG. 13, the switching pattern 122 includes the first interface region 116, the core region 118 formed on the first interface region 116, and the second interface region 120 formed on the core region 118. The switching pattern 122 may have a three-level concentration gradient.

Alternatively, when the switching material layer 122r (see FIG. 12) having a three-level concentration gradient is not formed by the in-situ type, the switching pattern 122 having the three-level concentration gradient may be formed by another type.

For example, the switching pattern 122 having the three-level concentration gradient may be formed by the ex-situ type using the reactivity difference (or the etching amount difference) between etching gas and materials to be etched when the first hard mask pattern HDM1 is used as an etching mask to etch the etching prevention material layer STPR (see FIG. 12), the upper electrode material layer 124r (see FIG. 12), the switching material layer 122r (see FIG. 12), the lower electrode material layer 114r (see FIG. 12), and the first conductive line material layer 112r (see FIG. 12). This will be described below in more detail.

In addition, as shown on the Y1-Y1′ cross-section of FIG. 13, a first gap 129 exposing the substrate 110 between every two groups of the first conductive line 112, the lower electrode layer 114, the switching pattern 122, the upper electrode layer 124, and an etching prevention layer STP is formed.

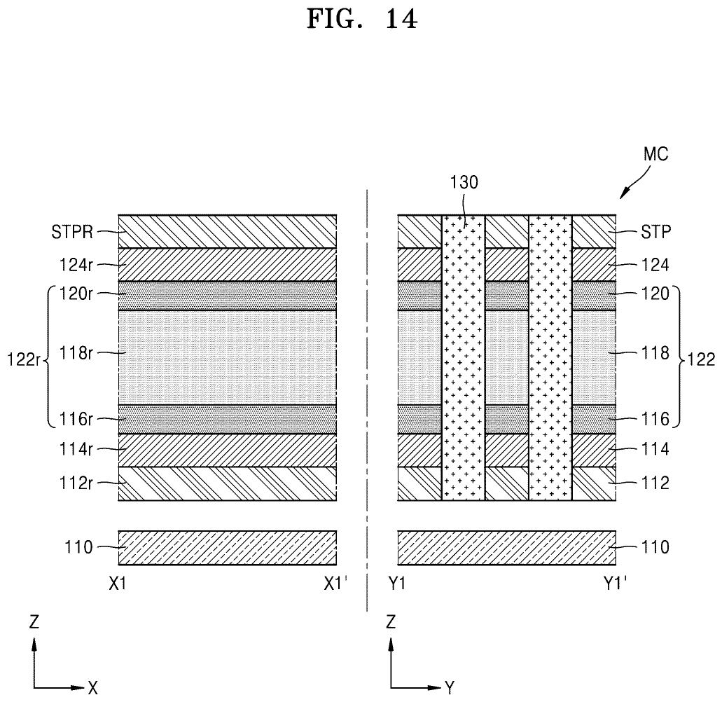

Referring to FIG. 14, as shown on the Y1-Y1′ cross-section of FIG. 14, a first gap fill layer 130 is formed in the first gap 129 (see FIG. 13). The first gap fill layer 130 may be formed by a dielectric layer or a spin on glass (SOG) layer.

The first gap fill layer 130 may be formed by forming a gap fill material layer in the first gap 129 (see FIG. 13) and then flattening the gap fill material layer through chemical mechanical polishing or etch-back up to the surface of the etching prevention layer STP as an etching stop point. When the first gap fill layer 130 is formed, the first hard mask pattern HDM1 (see FIG. 13) may also be polished and removed.

Through this process, as shown on the Y1-Y1′ cross-section of FIG. 14, the memory cell MC including the lower electrode layer 114, the switching pattern 122, and the upper electrode layer 124 may be formed on the first conductive line 112.

Referring to FIG. 15, the etching prevention material layer STPR (see FIG. 14), the etching prevention layer STP (see FIG. 14), and the first gap fill layer 130 (see FIG. 14) are etched back to expose the upper electrode material layer 124r of the X1-X1′ cross-section and the upper electrode layer 124 of the Y1-Y1′ cross-section.

Next, a second conductive line material layer 126r and a second hard mask material layer HDMR2 are formed on the upper electrode material layer 124r of the X1-X1′ cross-section and the upper electrode layer 124 and the first gap fill layer 130 of the Y1-Y1′ cross-section.

The second conductive line material layer 126r may include a metal, conductive metal nitride, conductive metal oxide, or a combination thereof. The second hard mask material layer HDMR2 may include a silicon oxide layer, a silicon nitride layer, a polysilicon layer, or another dielectric layer.

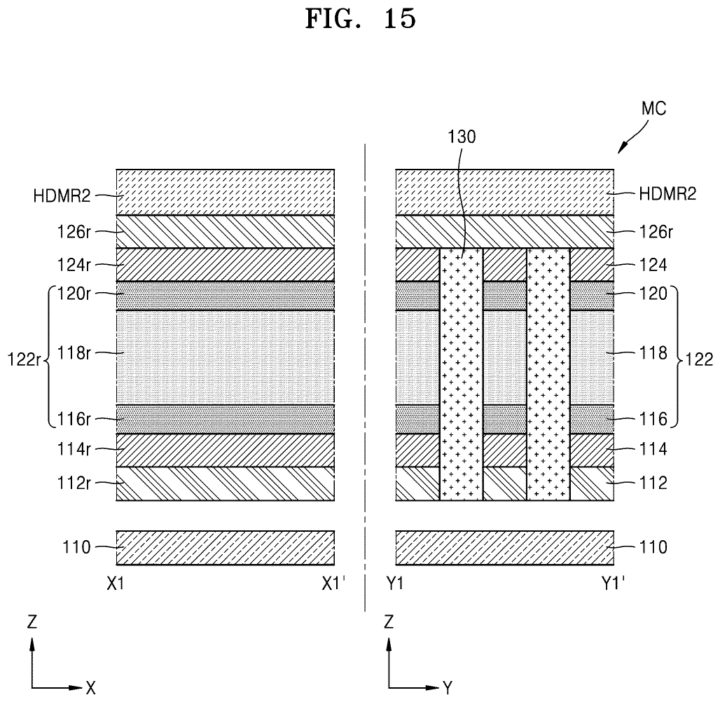

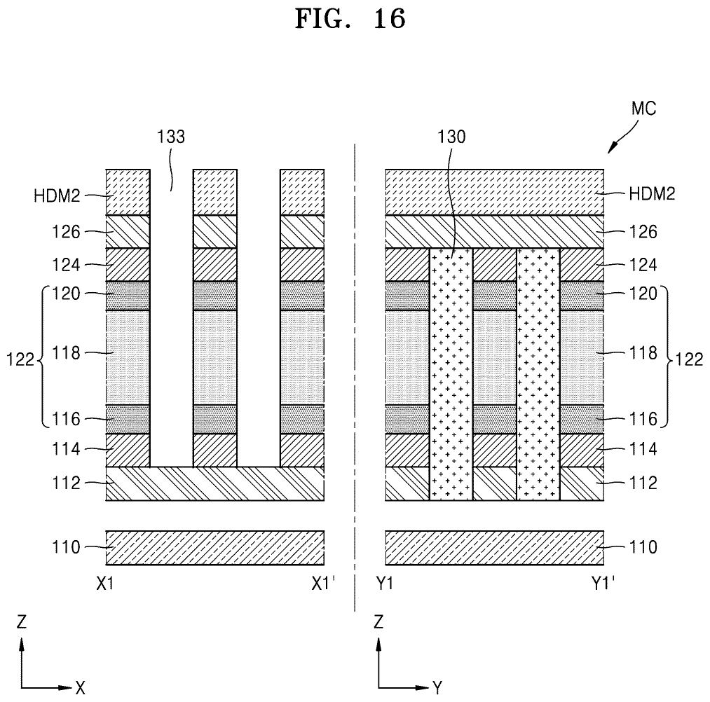

Referring to FIG. 16, a second hard mask pattern HDM2 is formed by patterning the second hard mask material layer HDMR2 (see FIG. 15). The second hard mask pattern HDM2 may be patterned using a photoresist pattern formed on the second hard mask material layer HDMR2 (see FIG. 15) through a photolithography process. In some implementations, the second hard mask pattern HDM2 may have a very fine pitch less than or equal to tens of nm.

The second hard mask pattern HDM2 may extend in the second horizontal direction (the Y direction). Multiple instances of the second hard mask patterns HDM2 may be separated from each other in the first horizontal direction (the X direction). The instances of the second hard mask patterns HDM2 extend on the Y1-Y1′ cross-section of FIG. 16 and are separated from each other on the X1-X1′ cross-section of FIG. 16.

The second hard mask pattern HDM2 is used as an etching mask to etch the second conductive line material layer 126r (see FIG. 15), the switching material layer 122r (see FIG. 15), the lower electrode material layer 114r (see FIG. 15), and the first conductive line material layer 112r (see FIG. 15).

Accordingly, as shown on the X1-X1′ cross-section of FIG. 16, the first conductive line 112, the lower electrode layer 114, the switching pattern 122, the upper electrode layer 124, and the second conductive line 126 may be formed above the substrate 110. The plurality of second conductive lines 126 may extend to be parallel to each other in the second horizontal direction (the Y direction) and be separated from each other in the first horizontal direction (the X direction) as described above. The second conductive line 126 may be referred to as a bit line.

As shown on the X1-X1′ cross-section of FIG. 16, the switching pattern 122 may include the first interface region 116, the core region 118 formed on the first interface region 116, and the second interface region 120 formed on the core region 118.

Alternatively, when the switching material layer 122r (see FIG. 12) having a three-level concentration gradient is not formed by the in-situ type, the switching pattern 122 having the three-level concentration gradient may be formed by another type.

For example, the switching pattern 122 having the three-level concentration gradient may be formed by the ex-situ type using the reactivity difference (or the etching amount difference) between etching gas and materials to be etched when the second hard mask pattern HDM2 is used as an etching mask to etch the second conductive line material layer 126r (see FIG. 15), the switching material layer 122r (see FIG. 15), the lower electrode material layer 114r (see FIG. 15), and the first conductive line material layer 112r (see FIG. 15).

In addition, as shown on the X1-X1′ cross-section of FIG. 16, a second gap 133 exposing the first conductive line 112 between every two groups of the lower electrode layer 114, the switching pattern 122, the upper electrode layer 124, and the etching prevention layer STP on the first conductive line 112 is formed.

Referring to FIG. 17, a second gap fill layer 134 is formed in the second gap 133 (see FIG. 16) as shown on the X1-X1′ cross-section of FIG. 16. The second gap fill layer 134 may be formed by a dielectric layer or an SOG layer.

The second gap fill layer 134 may be formed by forming a gap fill material layer in the second gap 133 (see FIG. 16) and then flattening the gap fill material layer through chemical mechanical polishing or etch-back up to the surface of the second conductive line 126 as an etching stop point. When the second gap fill layer 134 is formed, the second hard mask pattern HDM2 (see FIG. 16) may also be polished and removed.

Through this process, as shown on the X1-X1′ cross-section of FIG. 17, the memory cell MC including the lower electrode layer 114, the switching pattern 122, and the upper electrode layer 124 may be formed on the first conductive line 112. As a result, a memory device may have the memory cell MC including the lower electrode layer 114, the switching pattern 122, and the upper electrode layer 124 between the first conductive line 112 and the second conductive line 126 above the substrate 110 on the X1-X1′ cross-section and the Y1-Y1′ cross-section.

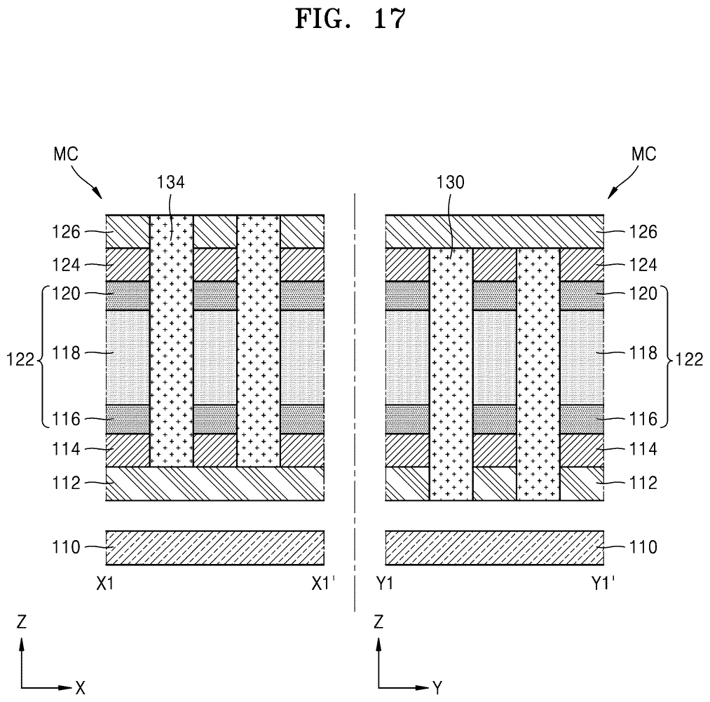

FIGS. 18 to 21 are cross-sectional views for describing a method of manufacturing the memory device 100 of FIGS. 1 and 2, according to some implementations.

Particularly, FIGS. 18 to 21 are provided to describe a method of forming the switching pattern 122 of FIGS. 12 and 13. FIGS. 18 to 21 are provided to describe that the switching pattern 122 having a three-level concentration gradient is formed by the ex-situ type. In FIGS. 18 to 21, like reference numerals in FIGS. 12 and 13 denote like members.

Referring to FIG. 18, the first conductive line material layer 112r, the lower electrode material layer 114r, a switching material layer 122r2, the upper electrode material layer 124r, the etching prevention layer STP, and the first hard mask layer HDM1 are formed above the substrate 110.

In some implementations, the lower electrode material layer 114r may include a carbon electrode or a carbon nitride electrode. The switching material layer 122r2 may include a chalcogenide layer including a chalcogen element of group VI of the periodic table and an element of group IV and an element of group V of the periodic table, which are chemically bonded to the group VI chalcogen element, as described above.

The group VI chalcogen element may include at least one of Te, Se, and S. The bonded group V element may include at least one of As, Sb, and P. The bonded group IV element may include at least one of Si and Ge.

In some implementations, the switching material layer 122r2 may further include a doping element of group III of the periodic table in addition to the elements described above. The group III doping element may include at least one of In, Ga, and Al.

The switching material layer 122r2 may be a material layer without the concentration gradient of the group IV element or the group V element in the vertical direction (the Z direction). In some implementations, the switching material layer 122r2 may include about 15 atom % to about 25 atom % of a group IV element, about 20 atom % to about 30 atom % of a group V element, and about 45 atom % to about 65 atom % of a group VI element. In some implementations, the upper electrode material layer 124r may include a carbon electrode or a carbon nitride electrode.

FIG. 18 shows that the first hard mask pattern HDM1 is used to pattern the etching prevention material layer STPR (see FIG. 12), thereby forming the etching prevention layer STP.

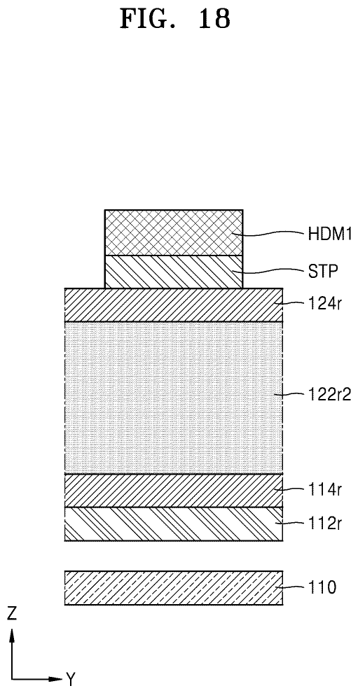

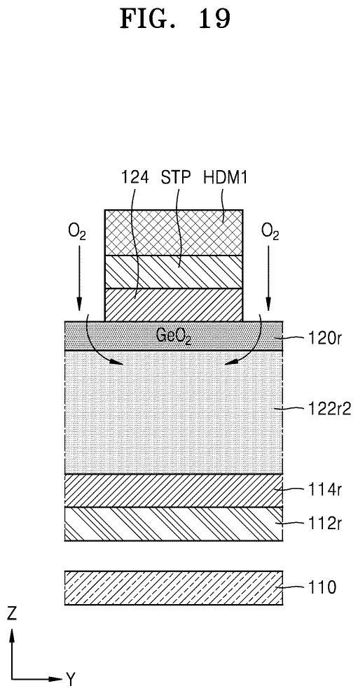

Referring to FIG. 19, the upper electrode layer 124 is formed by using the first hard mask pattern HDM1 and the etching prevention layer STP as an etching mask to etch the upper electrode material layer 124r. The upper electrode material layer 124r may be etched using oxygen gas. In a process of forming the upper electrode layer 124, the oxygen gas may infiltrate into an upper portion of the switching material layer 122r2 in contact with the upper electrode layer 124.

In the upper portion of the switching material layer 122r2 in contact with the upper electrode layer 124, a group IV element (e.g., Ge) easily being oxidated may be first oxidated and then become group IV oxide (e.g., GeO₂). The group IV oxide (e.g., germanium oxide (GeO₂)) may have a fast etching speed. Accordingly, the upper portion of the switching material layer 122r2 in contact with the upper electrode layer 124 may lose the group IV element (or Ge), thereby forming the second interface material layer 120r with a rich group V element (e.g., As).

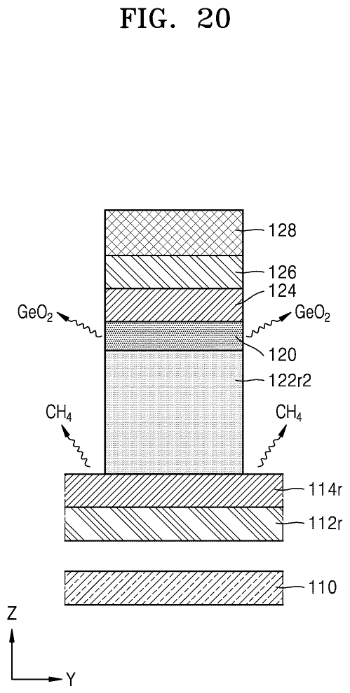

Referring to FIG. 20, when the first hard mask pattern HDM1 (see FIG. 19) and the etching prevention layer STP (see FIG. 19) are used as an etching mask to etch the switching material layer 122r2, group IV element oxide gas (or GeO₂ gas) may be discharged to the outside at the upper portion of the switching material layer 122r2, which is not covered by the upper electrode layer 124, thereby forming the second interface region 120. The second interface region 120 may lose the group IV element (or Ge) and become a region with a rich group V element (e.g., As). In addition, the second interface region 120 may be a region with a poor group IV element.

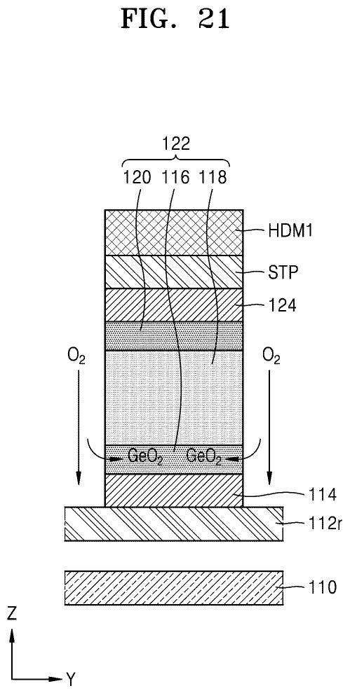

Referring to FIG. 21, the lower electrode layer 114 is formed by using the first hard mask pattern HDM1 and the etching prevention layer STP as an etching mask to etch the lower electrode material layer 114r (see FIG. 20). The lower electrode material layer 114r (see FIG. 20) may be etched using oxygen gas. In a process of forming the lower electrode layer 114, the oxygen gas may infiltrate into a lower portion of the switching material layer 122r2 (see FIG. 20) in contact with the lower electrode layer 114.

In the lower portion of the switching material layer 122r2 (see FIG. 20) in contact with the lower electrode material layer 114r (see FIG. 20), a group IV element (e.g., Ge) easily being oxidated may be first oxidated and then become group IV oxide (e.g., GeO₂). The group IV oxide (e.g., GeO₂) may have a fast etching speed. Accordingly, the lower portion of the switching material layer 122r2 (see FIG. 20) in contact with the lower electrode material layer 114r (see FIG. 20) may lose the group IV element (or Ge), thereby forming the first interface region 116 with a rich group V element (e.g., As). In addition, the first interface region 116 may be a region with a poor group IV element.

As a result, the switching material layer 122r2 (see FIG. 20) may be patterned and become the switching pattern 122 including the first interface region 116, the core region 118, and the second interface region 120 on the lower electrode layer 114. The switching pattern 122 may be configured to have a three-level concentration gradient of the group IV element or the group V element in the vertical direction (the Z direction). For example, the switching pattern 122 may have a low concentration level, a high concentration level, and a low concentration level of the group IV element in the vertical direction (the Z direction). The switching pattern 122 may have a high concentration level, a low concentration level, and a high concentration level of the group V element in the vertical direction (the Z direction).

In some implementations, the concentration of the group IV element in each of the first interface material layer 116r and the second interface region 120 may be lower than the concentration of the group IV element in the core region 118. The concentration of the group V element in each of the first interface region 116 and the second interface region 120 may be higher than the concentration of the group V element in the core region 118. The concentration of the group VI chalcogen element in each of the first interface region 116 and the second interface region 120 may be the same as the concentration of the group VI chalcogen element in the core region 118.

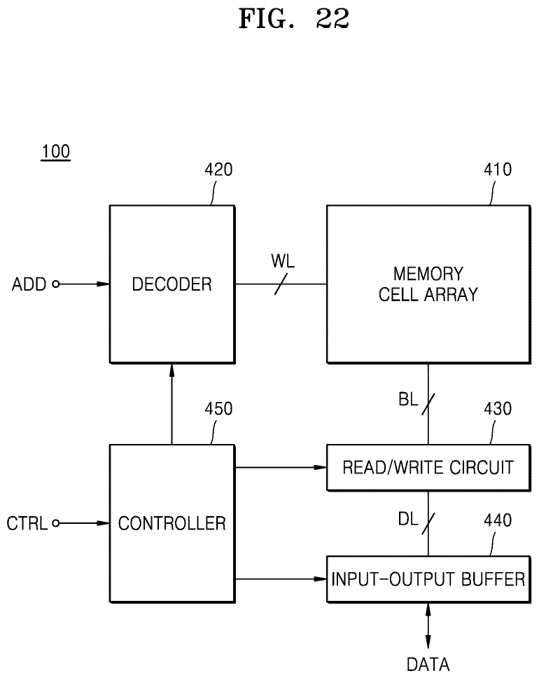

FIG. 22 is a block diagram of the memory device 100 according to some implementations.

Particularly, the memory device 100 according to some implementations includes a memory cell array 410, a decoder 420, a read/write circuit 430, an input-output buffer 440, and a controller 450. The memory cell array 410 has been described above, and thus, a description thereof is omitted herein.

A plurality of memory calls in the memory cell array 410 may be connected to the decoder 420 through word lines WL and connected to the read/write circuit 430 through bit lines BL.

The decoder 420 may receive an external address ADD and decode a row address and a column address to be accessed in the memory cell array 410, by control by the controller 450 operating in response to a control signal CTRL.

The read/write circuit 430 may record data DATA in a selected memory cell of the memory cell array 410 by control by the controller 450 by receiving the data DATA from the input-output buffer 440 through a data line DL or provide the data DATA read from the selected memory cell of the memory cell array 410 to the input-output buffer 440 by control by the controller 450.

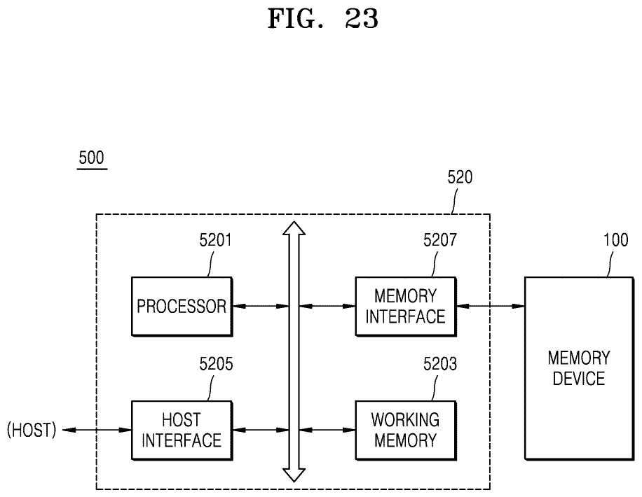

FIG. 23 is a block diagram of a data processing system 500 including the memory device 100 according to some implementations.

Particularly, the data processing system 500 includes a memory controller 520 connected between a host and the memory device 100. The memory controller 520 may be configured to access the memory device 100 in response to a request of the host. The memory controller 520 includes a processor 5201, a working (or operating) memory 5203, a host interface 5205, and a memory interface 5207.

The processor 5201 may control a general operation of the memory controller 520, and the working memory 5203 may store an application, data, a control signal, and the like required to operate the memory controller 520. The host interface 5205 may perform protocol conversion for data/control signal exchange between the host and the memory controller 520. The memory interface 5207 may perform protocol conversion for data/control signal exchange between the memory controller 520 and the memory device 100. The memory device 100 has been described above, and thus, a description thereof is omitted herein. The data processing system 500 may be a memory card but is not limited thereto.

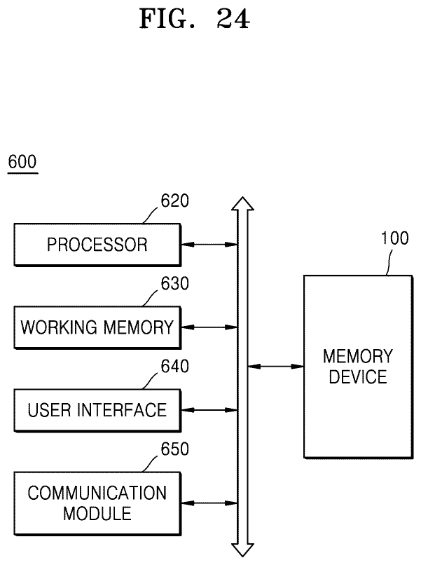

FIG. 24 is a block diagram of a data processing system 600 including the memory device 100 according to some implementations.

Particularly, the data processing system 600 includes the memory device 100, a processor 620, a working (or operating) memory 630, and a user interface 640 and may further include a communication module 650 in accordance with circumstances. The processor 620 may be a central processing unit.

The working memory 630 may store an application program, data, a control signal, and the like required to operate the data processing system 600. The user interface 640 may provide an environment in which a user accesses the data processing system 600, and provide a data processing process, a data processing result, and the like of the data processing system 600 to the user.

The memory device 100 has been described above, and thus, a description thereof is omitted herein. The data processing system 600 may be used as a disc device, an embedded/external memory card of a portable electronic device, an image processor, or other application chipset.

While the present disclosure has been described with reference to implementations thereof, it will be understood that various changes in form and details may be made therein without departing from the spirit and scope of the following claims.

What is claimed is:

1. A memory device comprising:
a first conductive line extending in a first horizontal direction;
a second conductive line extending in a second horizontal direction; and
a memory cell extending in a vertical direction between the first conductive line and the second conductive line,
wherein the memory cell comprises a lower electrode layer, a switching pattern, and an upper electrode layer, wherein the lower electrode layer, the switching pattern, and the upper electrode layer are sequentially stacked on the first conductive line,
wherein the switching pattern comprises a chalcogenide layer including:
a group VI chalcogen element of a periodic table, and
a combination of a group IV element and a group V element of the periodic table,
wherein the combination is chemically bonded to the group VI chalcogen element, and
wherein the switching pattern has a three-level concentration gradient of the group IV element or the group V element in the vertical direction.

2. The memory device of claim 1, wherein the switching pattern comprises a first interface region formed on the lower electrode layer, a core region formed on the first interface region, and a second interface region formed on the core region.

3. The memory device of claim 2, wherein a concentration of the group V element in each of the first interface region and the second interface region is higher than a concentration of the group V element in the core region.

4. The memory device of claim 2, wherein a concentration of the group IV element in each of the first interface region and the second interface region is lower than a concentration of the group IV element in the core region.

5. The memory device of claim 2, wherein a concentration of the group VI chalcogen element in each of the first interface region and the second interface region is the same as a concentration of the group VI chalcogen element in the core region.

6. The memory device of claim 1, wherein the group VI chalcogen element comprises at least one of tellurium (Te), selenium (Se), or sulfur (S),
wherein the group V element comprises at least one of arsenic (As), antimony (Sb), or phosphorous (P), and
wherein the group IV element comprises at least one of silicon (Si) or germanium (Ge).

7. The memory device of claim 1, wherein the switching pattern further comprises a group III doping element of the periodic table.

8. The memory device of claim 7, wherein the group III doping element comprises at least one of indium (In), gallium (Ga), or aluminum (Al).

9. The memory device of claim 1, wherein the switching pattern is configured so that a concentration gradient of a bonded element including the combination and the group VI chalcogen element remains unchanged before and after applying an operating voltage to the switching pattern.

10. A memory device comprising:
a first conductive line extending in a first horizontal direction;
a second conductive line extending in a second horizontal direction; and
a memory cell extending in a vertical direction between the first conductive line and the second conductive line,
wherein the memory cell comprises a lower electrode layer, a switching pattern, and an upper electrode layer, wherein the lower electrode layer, the switching pattern, and the upper electrode layer are sequentially stacked on the first conductive line,
wherein the switching pattern comprises a chalcogenide layer including: a group VI chalcogen element of a periodic table, and a combination of a group IV element and a group V element of the periodic table, wherein the combination is chemically bonded to the group VI chalcogen element,
wherein the switching pattern comprises a first interface region on the lower electrode layer, a core region on the first interface region, and a second interface region on the core region,
wherein a concentration of the group IV element in each of the first interface region and the second interface region is lower than a concentration of the group IV element in the core region, and
wherein a concentration of the group V element in each of the first interface region and the second interface region is higher than a concentration of the group V element in the core region.

11. The memory device of claim 10, wherein the group VI chalcogen element comprises at least one of tellurium (Te), selenium (Se), or sulfur (S), the group V element comprises at least one of arsenic (As), antimony (Sb), or phosphorous (P), and the group IV element comprises at least one of silicon (Si) or germanium (Ge).

12. The memory device of claim 11, wherein the first interface region and the second interface region comprise about 10 atom % to about 20 atom % of a group IV element, about 25 atom % to about 40 atom % of a group V element, and about 40 atom % to about 65 atom % of a group VI chalcogen element.

13. The memory device of claim 11, wherein the core region comprises about 15 atom % to about 25 atom % of a group IV element, about 20 atom % to about 30 atom % of a group V element, and about 45 atom % to about 65 atom % of a group VI chalcogen element.

14. The memory device of claim 11, wherein the switching pattern further comprises a group III doping element of the periodic table.

15. The memory device of claim 14, wherein the group III doping element comprises at least one of indium (In), gallium (Ga), or aluminum (Al).

16. The memory device of claim 10, wherein the switching pattern is configured so that a concentration gradient of a bonded element including the combination and the group VI chalcogen element remains unchanged when a polarity of an operating voltage applied to the lower electrode layer and the upper electrode layer changes.

17. A memory device comprising:
a first conductive line extending in a first horizontal direction;
a second conductive line extending in a second horizontal direction; and
a memory cell extending in a vertical direction between the first conductive line and the second conductive line,
wherein the memory cell comprises a lower electrode layer, a switching pattern, and an upper electrode layer, wherein the lower electrode layer, the switching pattern, and the upper electrode layer are sequentially stacked on the first conductive line,
wherein the switching pattern comprises a chalcogenide layer including: a group VI chalcogen element of a periodic table; and a combination of a group IV element and a group V element of the periodic table, wherein the combination is, chemically bonded to the group VI chalcogen element,
wherein the switching pattern comprises a first interface region formed on the lower electrode layer, a core region formed on the first interface region, and a second interface region formed on the core region,
wherein the core region comprises an impurity layer of a first conductive type, and
wherein the first interface region and the second interface region comprise an impurity layer of a second conductive type that is opposite to the first conductive type.

18. The memory device of claim 17, wherein the core region comprises a P-type impurity layer, and the first interface region and the second interface region comprise an N-type impurity layer.

19. The memory device of claim 17, wherein a concentration of the group IV element in each of the first interface region and the second interface region is lower than a concentration of the group IV element in the core region, and a concentration of the group V element in each of the first interface region and the second interface region is higher than a concentration of the group V element in the core region.

20. The memory device of claim 17, wherein the switching pattern further comprises a group III doping element of the periodic table, the group VI chalcogen element comprises at least one of tellurium (Te), selenium (Se), or sulfur (S), the group V element comprises at least one of arsenic (As), antimony (Sb), or phosphorous (P), the group IV element comprises at least one of silicon (Si) or germanium (Ge), and the group III doping element comprises at least one of indium (In), gallium (Ga), or aluminum (Al).
